(19) United States
(12) Patent Application Publication
(10) Pub. No.: US 2020/0006574 A1
(43) Pub. Date: Jan. 2, 2020

(54) THIN FILM TRANSISTOR, METHOD FOR MANUFACTURING THE THIN FILM TRANSISTOR, AND DISPLAY PANEL

(71) Applicants: HKC Corporation Limited, Shenzhen (CN); Chongqing HKC Optoelectronics Technology Co., Ltd., Chongqing (CN)

(72) Inventor: Entsung Cho, Shenzhen (CN)

(21) Appl. No.: 16/254,580

(22) Filed: Jan. 22, 2019

Related U.S. Application Data
(63) Continuation of application No. PCT/CN2018/119174, filed on Dec. 4, 2018.

(30) Foreign Application Priority Data
Jul. 2, 2018 (CN) 201810707203.2

(51) Int. Cl. H01L 29/786; H01L 29/66; H01L 29/417; H01L 21/308; H01L 21/02

(52) U.S. Cl. CPC H01L 29/78669; H01L 29/78678; H01L 29/66765; H01L 27/3248; H01L 21/308; H01L 21/02274; H01L 29/41733

(57) ABSTRACT

The present disclosure provides a thin film transistor, a manufacturing method thereof, and a display panel. The thin film transistor includes a substrate, a gate electrode, a gate insulating layer, a semiconductor layer, a doping layer, and a source drain electrode all formed on the substrate in sequence, the semiconductor layer absorbs light having a wavelength greater than 760 nanometers.

### CROSS REFERENCE TO RELATED APPLICATIONS

The present application is a Continuation Application of PCT Application No. PCT/CN2018/119174 filed on Dec. 4, 2018, which claims the benefit of Chinese Patent Application No. 201810707203.2, filed on Jul. 2, 2018, which is incorporated herein by reference in its entirety.

### FIELD

The exemplary embodiment of the present disclosure generally relates to the technical field of transistor, and more particularly relates to a thin film transistor, a method for manufacturing the thin film transistor, and a display panel.

### BACKGROUND

Thin film transistor is the key component of the display panel and plays a very important role in the performance of the display panel. With the rapid development of electronic equipment, people require the electronic equipment to have much lower power consumption, and better cruising ability. Therefore the display panel of the electronic equipment is also required to be low power consumption.

A thin film transistor array substrate is arranged in the display panel, however, the leakage current of the thin film transistor of the current thin film transistor array substrate is relatively large, and photogenerated carriers are also generated when light irradiates on the thin film transistor, further increasing the leakage current of the thin film transistor, resulting in higher power consumption of the display panel and poor stability of the thin film transistor.

### SUMMARY

It is therefore one main object of the disclosure to provide a thin film transistor, a method for manufacturing the thin film transistor, and a display panel, so as to reduce the leakage current of the thin film transistor and improve the stability of the thin film transistor.

The exemplary embodiment of the present disclosure provides a thin film transistor, which includes:

a substrate;

a gate electrode, a gate insulating layer, a semiconductor layer, a doping layer, and a source drain electrode all defined on the substrate in sequence, the semiconductor layer absorbing light having a wavelength greater than 760 nanometers.

Furthermore, the thin film transistor is manufactured by four mask processes, which sequentially includes: forming a source drain metal layer by a one-time wet etching process, forming a doping film and a semiconductor film by a one-time dry etching process and ashing photoresist, forming the source drain electrode by a one-time wet etching process, and forming the doping layer and the semiconductor layer by alone-time dry etching process.

Furthermore, a material of the semiconductor layer includes microcrystalline silicon, microcrystalline silicon germanium, or microcrystalline germanium.

The exemplary embodiment of the present disclosure provides a method for manufacturing a thin film transistor, which includes:

providing a substrate;

forming a gate electrode, a gate insulating layer, a semiconductor layer, a doping layer, and a source drain electrode on the substrate in sequence, the semiconductor layer absorbs light having a wavelength greater than 760 nanometers.

Furthermore, a material of the semiconductor layer includes microcrystalline silicon, microcrystalline silicon germanium, or microcrystalline germanium.

Furthermore, the semiconductor layer is formed by a plasma enhanced chemical vapor deposition.

Furthermore, the material of the semiconductor layer includes microcrystalline silicon, and reaction gases for forming the semiconductor layer includes: hydrogen H₂ and silicon tetrahydride SiH₄, a gas volume ratio of H₂ to SiH₄ is greater than or equal to 20:1 and less than or equal to 180:1.

the material of the semiconductor layer includes microcrystalline silicon germanium, and reaction gases for forming the semiconductor layer includes: hydrogen H₂, silicon tetrahydride SiH₄ and germanium hydride GeH₄, a gas volume ratio of H₂ to SiH₄ is greater than or equal to 20:1 and less than or equal to 180:1, the gas volume ratio of H₂ to GeH₄ is greater than or equal to 20:1 and less than or equal to 180:1, and the gas volume ratio of GeH₄ to SiH₄ is greater than or equal to 1:10.

Furthermore, the material of the semiconductor layer includes microcrystalline germanium, and reaction gases for forming the semiconductor layer includes hydrogen H₂ and germanium hydride GeH₄, a gas volume ratio of H₂ to GeH₄ is greater than or equal to 20:1 and less than or equal to 180:1.

The exemplary embodiment of the present disclosure further provides a display panel, the display panel includes a thin film transistor array substrate which includes a thin film transistor as described above.

According to the thin film transistor provided by the exemplary embodiment of the present disclosure, its semiconductor layer absorbs light with a wavelength greater than 760 nanometers, that is the semiconductor layer does not absorb visible light, when the light irradiates on the thin film transistor, even if the light irradiates on the semiconductor layer of the thin film transistor, the semiconductor layer of the thin film transistor would not absorb light, nor would it react with visible light to generate light leakage current, thus the leakage current of the thin film transistor would not be increased. Compared with the prior art, the leakage current of the thin film transistor is reduced, the electrical performance stability of the thin film transistor is correspondingly improved, and when the thin film transistor is applied to the display panel, the power consumption of the display panel can also be reduced.

### BRIEF DESCRIPTION OF THE DRAWINGS

To better illustrate the technical solutions that are reflected in various embodiments according to the disclosure or that are found in the prior art, the accompanying drawings intended for the description of the embodiments herein or for the prior art will now be briefly described, it is evident that the accompanying drawings listed in the following description show merely some embodiments according to the disclosure, and that those having ordinary skill in the art will be able to obtain other drawings based on the arrangements shown in these drawings without making inventive efforts.

FIG. 1 is a diagram of the thin film transistor provided as an example;

FIG. 2 is a diagram of the thin film transistor of the present disclosure provided by an exemplary embodiment;

FIG. 3 is a flow chart of the method for manufacturing the thin film transistor of the present disclosure provided by an exemplary embodiment;

FIG. 4 is a diagram of the display panel of the present disclosure provided by an exemplary embodiment;

FIG. 5 is a flow chart of the method for manufacturing the thin film transistor shown in FIG. 2;

FIG. 6A to 6E are transmission electron microscope diffraction diagrams of the microcrystalline silicon layers formed in different gas volume ratios of H₂ to SiH₄ of the present disclosure provided by an exemplary embodiment;

FIG. 7 is an absorption waveform diagram of the amorphous silicon and microcrystalline silicon.

### DETAILED DESCRIPTION

The realization of the aim, functional characteristics, advantages of the present disclosure are further described specifically with reference to the accompanying drawings and embodiments. It is obvious that the embodiments to be described are only a part rather than all of the embodiments of the present disclosure. All other embodiments obtained by persons skilled in the art based on the embodiments of the present disclosure without creative efforts shall fall within the protection scope of the present disclosure.

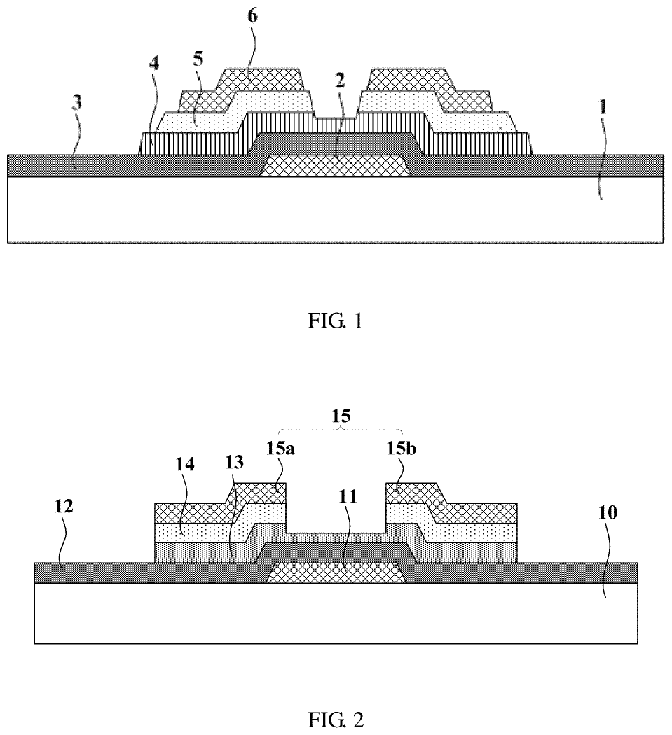

Referring to FIG. 1, which is a diagram of the thin film transistor provided as an example. The thin film transistor is formed by a 4-mask process. Specifically, the thin film transistor includes a substrate 1, a gate electrode 2, a gate insulating layer 3, an amorphous silicon layer 4, a doping layer 5, and a source drain electrode 6. In the actual manufacturing process, if the edge of the formed amorphous silicon layer 4 is beyond the edge of the source drain electrode 6, a tail is formed, so when the thin film transistor having the tail is applied to the liquid crystal display panel, the area of the amorphous silicon layer 4 beyond the edge of the source drain electrode 6 will directly contact or absorb visible light emitted from the backlight module of the liquid crystal display panel. The amorphous silicon layer 4 will react with visible light to generate a light leakage current, thereby further increasing the leakage current of the thin film transistor, therefore the display panel would consume a larger power, and the electrical performance of the thin film transistor may also become unstable.

In order to solve the above problems, referring to FIG. 2, a thin film transistor according to an embodiment of the present disclosure is provided. The thin film transistor (TFT) includes a substrate 10, and a gate electrode 11, a gate insulating layer 12, a semiconductor layer 13, a doping layer 14 and a source drain electrode 15 which are sequentially formed on the substrate 10. The semiconductor layer 13 absorbs light having a wavelength greater than 760 nanometers. The gate electrode 11 and the source electrode 15a, and the gate electrode 11 and the drain electrode 15b of the TFT are all separated by the gate insulating layer 12. Therefore, the TFT can be actually defined as an insulated gate type field effect transistor, and the TFT can be divided into n type and p type.

Here, take an N type TFT, that is NTFT, as an example to briefly describe the operation principle of the TFT. When a positive voltage greater than a conduction voltage of NTFT is applied to the gate electrode 11, an electric field will be generated between the gate electrode 11 and the semiconductor layer 13. Under the action of the electric field, a conductive channel will be formed in the semiconductor layer 13 to form a conductive state between the source electrode 15a and the drain electrode 15b. The larger the voltage applied to the gate electrode 11, the larger the conductive channel will be. At this time, carriers would pass through the conductive channel by applying a voltage between the source electrode 15a and the drain electrode 15b. When a negative voltage lower than the conduction voltage of NTFT is applied to the gate electrode 11, no electron channel is formed in the semiconductor layer 13, and a closed state is formed between the source electrode 15a and the drain electrode 15b. The doping layer 14 is formed between the semiconductor layer 13 and the source 15a, and the semiconductor layer 13 and the drain 15b for reducing the resistance of the signals of the semiconductor layer 13 and the source and drain 15. Those skilled in the art can understand that the functions of the structures such as the substrate 10, the gate electrode 11, the gate insulating layer 12, the semiconductor layer 13, the doping layer 14 and the source drain electrode 15 of the thin film transistor provided by the exemplary embodiment of the present disclosure are similar to those of the prior art, and n need to repeat again.

In the embodiment of the present disclosure, the semiconductor layer 13 absorbs light with a wavelength greater than 760 nanometers, and the visible light wavelength is less than or equal to 760 nanometers, so the semiconductor layer 13 does not absorb visible light. When the light irradiates the thin film transistor, even if the light irradiates the semiconductor layer 13 of the thin film transistor, the semiconductor layer 13 of the thin film transistor would not absorb the light based on the characteristic that the semiconductor layer 13 does not absorb visible light, and would not react with the visible light to cause the light leakage current, thus the leakage current of the thin film transistor would not increase, the leakage current of the thin film transistor is reduced compared with the prior art, and correspondingly the electrical performance stability of the thin film transistor is improved.

Electively, in the embodiment of the present disclosure, the thin film transistor is manufactured by the 4-mask process, which sequentially includes forming a source drain metal layer by a one-time wet etching process, forming a doping film and a semiconductor film by a one-time dry etching process, and ashing photoresist, forming the source drain electrode by a one-time wet etching process, and forming the doping layer and the semiconductor layer by a one-time dry etching process.

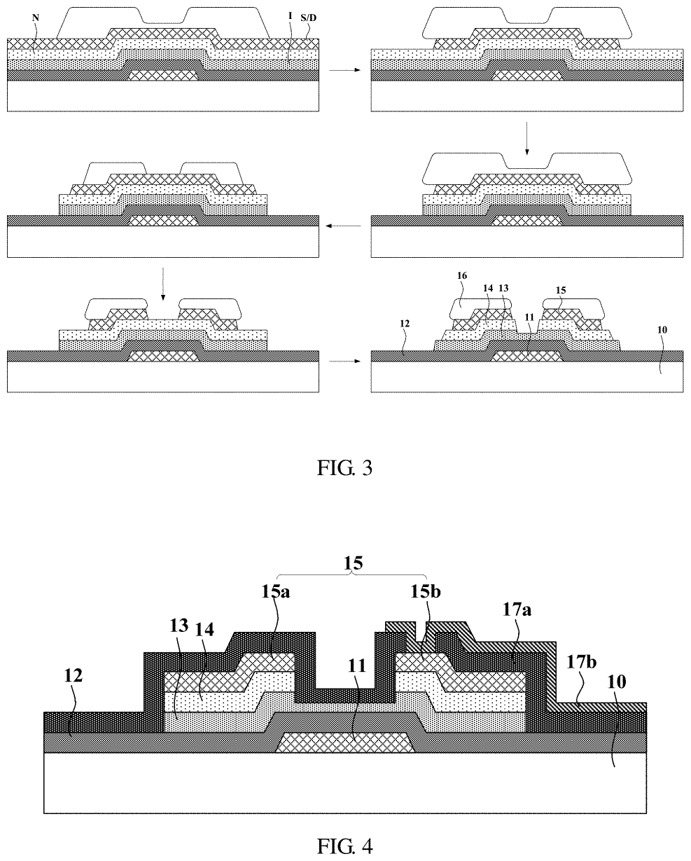

Referring to FIG. 3, a manufacturing flow chart of the thin film transistor is shown. Compared with the current 5-mask process, the 4-mask process has the advantages of reducing a photolithography process, shortening TFT process time and low cost. In detail, the 4-mask process includes: providing a substrate 10, forming a gate electrode 11, a gate insulating layer 12, a semiconductor film I, a doping film N, and a source-drain metal layer S/D on the substrate 10 sequentially. After forming the source-drain metal layer S/D, the difference between the 5-mask process and the 4-mask process is that: the etching process of the 4-mask process uses a 2W2D (2 wet etching 2 dry etching, two wet etchings and two dry etchings) process to form the source drain electrode 15, the doping layer 14, and the semiconductor layer 13.

The etching process of the 4-mask process adopts 2W2D process, that is, two wet etchings and two dry etchings, which specifically includes: forming the source drain metal layer S/D by one wet etching process, forming the doping film N and the semiconductor film I by one dry etching process, and ashing the photoresist 16, forming the source drain electrode 15 by one wet etching process, and forming the doping layer 14 and the semiconductor layer 13 by one dry etching process.

Electively, the material of the semiconductor layer 13 in the embodiment of the present disclosure includes microcrystalline silicon, microcrystalline silicon germanium, or microcrystalline germanium. In the prior art, the thin film transistor defines an amorphous silicon layer 4 between the gate insulating layer 3 and the doping layer 5, and the amorphous silicon layer 4 is sensitive to visible light. That is, after contacting or absorbing visible light, the amorphous silicon layer 4 reacts with visible light to generate light leakage current, further increasing the leakage current of the thin film transistor, which may result in unstable electrical performance of the thin film transistor. However, microcrystalline silicon, microcrystalline silicon germanium, or microcrystalline germanium are not sensitive to visible light, and the wavelength of the absorbed light is more than 760 nanometers, while the wavelength of visible light is less than or equal to 760 nanometers. Therefore, microcrystalline silicon, microcrystalline silicon germanium, or microcrystalline germanium does not absorb visible light, and even if it contacts with visible light, it will not react with visible light to generate the light leakage current. In the embodiment of the present disclosure, the semiconductor layer 13 includes microcrystalline silicon, microcrystalline silicon germanium, or microcrystalline germanium. Compared with the prior art, the leakage current of the thin film transistor can be reduced and the electrical performance stability of the thin film transistor can be correspondingly improved. When the thin film transistor is applied to the display panel, the power consumption of the display panel can also be reduced.

It would be understood by those skilled in the art that, the film structure, the manufacturing process and the material of the semiconductor of the thin film transistor, include, but not limited to, the above examples, any kind of thin film transistor structure, the process of manufacturing the thin film transistor, and the material that can be used as the semiconductor of the thin film transistor and does not absorb visible light, would fall within the scope of the present disclosure.

According to the thin film transistor provided by the embodiment of the present disclosure, the semiconductor layer absorbs light with a wavelength greater than 760 nanometers, that is, the semiconductor layer does not absorb visible light, even if the light irradiates the semiconductor layer of the thin film transistor, based on the characteristic that the semiconductor layer does not absorb visible light the semiconductor layer of the thin film transistor would not absorb light, nor would it react with visible light to cause light leakage current, thus the leakage current of the thin film transistor may not be increased. Compared with the prior art, the leakage current of the thin film transistor is reduced, the electrical performance stability of the thin film transistor is correspondingly improved, and when the thin film transistor is applied to the display panel, the power consumption of the display panel can also be reduced.

The exemplary embodiment of the present disclosure also provides a display panel, which includes a thin film transistor array substrate, and the thin film transistor array substrate includes the thin film transistor as described above. It should be noted that as shown in FIG. 4, the thin film transistor is electrically connected to the pixel electrode 17b through the insulating layer 17a so as to transmit the data line signal to the corresponding pixel electrode 17b when it is turned on, and other structures of the display panel will not be specifically shown here. Compared with the prior art, the semiconductor layer of the thin film transistor does not react with visible light to generate light leakage current, thus reducing the leakage current of the thin film transistor, the electrical performance stability of the thin film transistor is correspondingly improved, and simultaneously the power consumption of the display panel is reduced. Alternatively, the display panel may be a liquid crystal display panel or an organic light emitting display panel.

Those skilled in the art can understand that the application range of the thin film transistor includes but is not limited to the display panel, and any electronic device that can integrate the above thin film transistor falls within the protection range of the present disclosure.

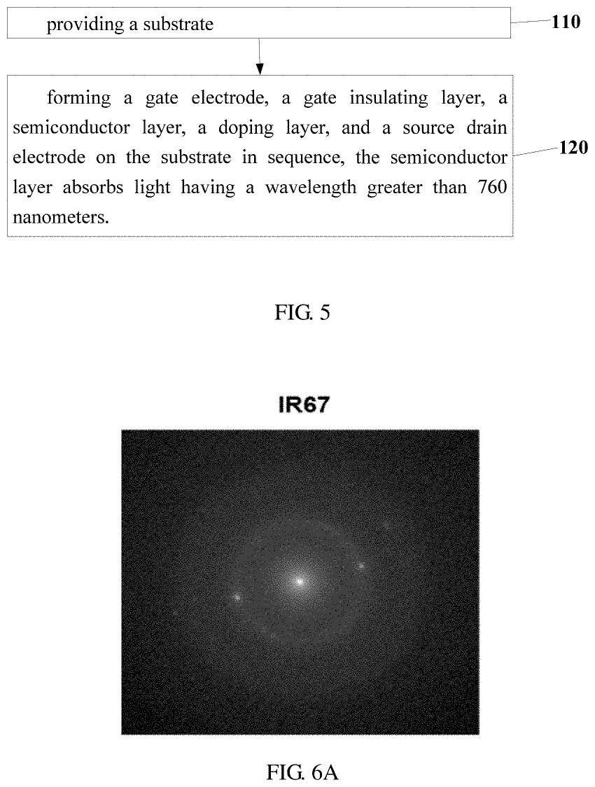

Referring to FIG. 5, a method for manufacturing the thin film transistor shown in FIG. 2 specifically includes the following steps:

Step 110: providing a substrate. In the embodiment, the substrate may be a glass substrate or a flexible substrate. Those skilled in the art can understand that the substrate materials of the selected thin film transistors are different when the application products of the thin film transistors are different. Obviously, the substrate material includes, but is not limited to, glass substrates and flexible substrates, and any material that can be used as the substrate of the thin film transistors falls within the scope of protection of the present disclosure.

Step 120: sequentially forming a gate electrode, a gate insulating layer, a semiconductor layer, a doping layer and a source drain electrode on the substrate, the semiconductor layer absorbs light with a wavelength greater than 760 nanometers.

In the embodiment, electively, the gate electrode is made of aluminum (Al) or molybdenum (Mo), the gate insulating layer is made of silicon nitride, the semiconductor layer is made of a semiconductor material capable of being used as a semiconductor for thin film transistors and absorbing light with a wavelength greater than 760 nanometers, the doping layer is made of N-type amorphous silicon or P-type amorphous silicon, and materials of the source drain electrode includes molybdenum nitride (MoN), aluminum (Al) and molybdenum nitride (MoN) which are sequentially stacked. Those skilled in the art would understand that the materials of the films of the thin film transistor include, but are not limited to, the above examples, and the materials of any film structure of the thin film transistor fall within the scope of the present disclosure. The manufacturing process of each film structure is not specifically described in the present disclosure, the materials of any film structure of the thin film transistor fall within the protection scope of the present disclosure.

Electively, the material of the semiconductor layer includes microcrystalline silicon, microcrystalline silicon germanium, or microcrystalline germanium. Microcrystalline silicon, microcrystalline silicon germanium, or microcrystalline germanium are not sensitive to visible light, and even if they are directly contact with visible light, they will not react with visible light to cause light leakage current. Therefore, in the embodiment of the present disclosure, the semiconductor layer adopts microcrystalline silicon, microcrystalline silicon germanium, or microcrystalline germanium, which can reduce the leakage current of the thin film transistor, and correspondingly the electrical performance stability of the thin film transistor is improved.

Electively, the semiconductor layer is formed by plasma enhanced chemical vapor deposition. Plasma enhanced chemical vapor deposition (PECVD) is the local formation of plasma by ionizing gas containing atoms of thin film composition with the help of microwave or radio frequency. The plasma has strong chemical activity and is easy to react, and the chemical reaction temperature is low, so the required film can be deposited.

Electively, the material of the semiconductor layer include microcrystalline silicon, and the reaction gases for forming the semiconductor layer include hydrogen H₂ and SiH₄, the gas volume ratio of H₂ to SiH₄ is greater than or equal to 20:1 and less than or equal to 180:1. In the embodiment, the material of the semiconductor layer includes microcrystalline silicon, so the gas for forming the microcrystalline silicon layer needs to include H₂ and SiH₄. After the ionization reaction of H₂ and SiH₄, the microcrystalline silicon layer containing Si, i.e., the semiconductor layer, can be formed on the gate insulating layer. Those skilled in the art can understand that the PECVD process can be used to deposit microcrystalline silicon layers with H₂ and SiH₄ as reaction gases, and the process will not be described in detail here.

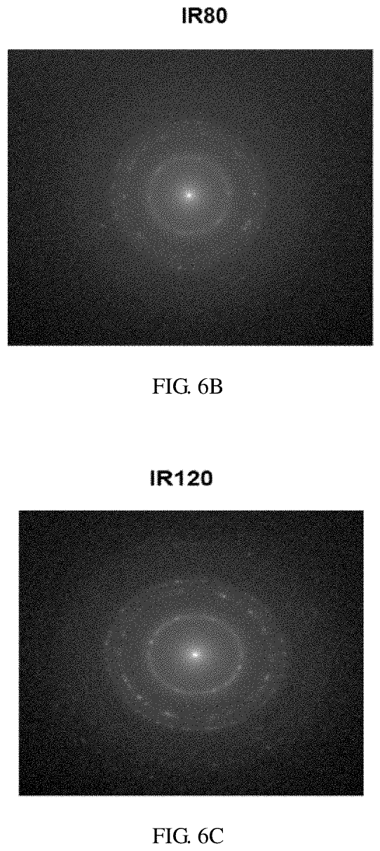

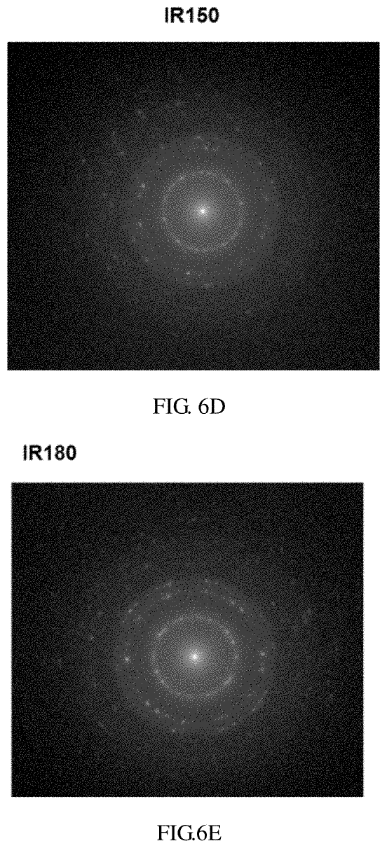

The gas volume ratio of H₂ to SiH₄ is selected to be greater than or equal to 20:1 and less than or equal to 180:1. When H₂/SiH₄ is lower than 20:1, the crystallinity of microcrystalline silicon layer is poor. When the ratio of H₂/SiH₄ is larger, the crystallinity of microcrystalline silicon is better and the ratio of absorbing infrared light is higher and higher. Here, the transmission electron microscope diffraction diagrams of the microcrystalline silicon layer formed in different gas volume ratios H₂/SiH₄ shown in FIGS. 6A to 6E are taken as examples to explain the influence of different gas volume ratios H₂/SiH₄ on the crystallinity of microcrystalline silicon.

FIG. 6A shows the crystallization effect of the microcrystalline silicon with that H₂/SiH₄ equals to 67:1 (Labeled as IR67), and it is obvious that the microcrystalline silicon has already partially crystallized. At this time, the absorption band of the microcrystalline silicon layer does not overlap with the visible light band and shifts to the infrared light band, so the microcrystalline silicon layer does not absorb visible light and does not generate light leakage current when applied as the semiconductor layer.

FIG. 6B shows the crystallization effect of the microcrystalline silicon with that H₂/SiH₄ equals to 80:1 (Labeled as IR80). Obviously, the crystallization of microcrystalline silicon increases and is superior to that of FIG. 6a. At this time, the absorption band of the microcrystalline silicon layer does not overlap with the visible light band and shifts to the infrared light band, so the microcrystalline silicon layer does not absorb visible light and does not generate light leakage current when applied as the semiconductor layer.

FIG. 6C shows the crystallization effect of the microcrystalline silicon with that H₂/SiH₄ equals to 120:1 (Labeled as IR120). Obviously, the crystallization of microcrystalline silicon increases and is superior to that of FIG. 6B. At this time, the absorption band of the microcrystalline silicon layer does not overlap with the visible light band and shifts to the infrared light band, so the microcrystalline silicon layer does not absorb visible light and does not generate light leakage current when applied as the semiconductor layer.

FIG. 6D shows the crystallization effect of the microcrystalline silicon with that H₂/SiH₄ equals to 150:1 (Labeled as IR 150). Obviously, the crystallization of microcrystalline silicon increases and is superior to that of FIG. 6C. At this time, the absorption band of the microcrystalline silicon layer does not overlap with the visible light band and shifts to the infrared light band, so the microcrystalline silicon layer does not absorb visible light and does not generate light leakage current when applied as the semiconductor layer.

FIG. 6E shows the crystallization effect of the microcrystalline silicon with that H₂/SiH₄ equals to 180:1 (Labeled as IR 180). Obviously, the crystallization of microcrystalline silicon increases and is superior to that of FIG. 6D. At this time, the absorption band of the microcrystalline silicon layer does not overlap with the visible light band and shifts to the infrared light band, so the microcrystalline silicon layer does not absorb visible light and does not generate light leakage current when applied as the semiconductor layer. It should be noted that the light emitting rings shown in FIGS. 6A to 6E are crystal axes, and the appearance of the crystal axis indicates that the microcrystalline silicon layer starts to crystallize.

It is also optional that H₂/SiH₄ is greater than or equal to 60:1. At this time, the crystallinity of the microcrystalline silicon layer is getting better and better, and the absorption band of the microcrystalline silicon layer is also located in the infrared light band, i.e. the ratio of infrared light absorption is higher and higher and no visible light is absorbed, thus no light leakage current would be generated.

It should be noted that the working parameters of adopting PECVD to deposit microcrystalline silicon layer are as follows: the temperature for forming microcrystalline silicon in PECVD may be in the range of 200 degrees Celsius to 500 degrees Celsius, specifically 370 degrees Celsius. The deposition may last 120 seconds to 900 seconds, specifically 120 seconds. The plasma rotational speed power can be selected as 500 W to 2600 W. The distance from the plasma to the glass may be 700 mil to 1000 mil, specifically 962 mil. The pressure of electron microscope environment can be 1400 mTorr to 3000 mTorr. The gas flow rate of H₂ may be 70000 sccm to 100000 sccm. The gas flow rate of SiH₄ can be selected as 500 SCCM. The thickness of the microcrystalline silicon layer can be selected from 800 Å to 1500 Å.

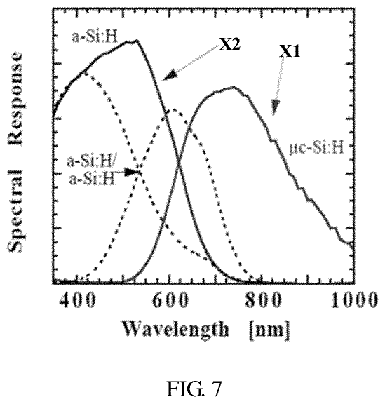

FIG. 7 also shows an absorption waveform diagram of the amorphous silicon and microcrystalline silicon, where the abscissa is wavelength nanometers and the ordinate is spectral response. It can be seen that the absorption band of the absorption waveform of microcrystalline silicon (X1) is biased toward the infrared band, and the absorption band of the absorption waveform of amorphous silicon (X2) is located in the visible band. The reason is that the forbidden band gap of microcrystalline silicon (uc-Si) is about 1.3 eV to 1.6 eV, and that of amorphous silicon is about 1.7 eV to 1.8 eV. However, the smaller the band gap, the easier it is for the material to absorb long wavelength light, and the absorption band of amorphous silicon is in the visible light band. Obviously, the absorption band of microcrystalline silicon with a band gap smaller than amorphous silicon moves toward the infrared light band longer than the visible light band. Those skilled in the art can make the absorption band of the microcrystalline silicon layer completely non-overlapping with the visible light band by adjusting the parameter characteristics of the microcrystalline silicon layer, for example, the absorption band of the microcrystalline silicon layer can be adjusted to exceed 800 nm.

Electively, the materials of the semiconductor layer include microcrystalline silicon germanium, and the reaction gases for forming the semiconductor layer include hydrogen H₂, silicon tetrahydride SiH₄, and germanium hydride GeH₄, a gas volume ratio of H₂ to SiH₄ is greater than or equal to 20:1 and less than or equal to 180:1, the gas volume ratio of H₂ to GeH₄ is greater than or equal to 20:1 and less than or equal to 180:1, and the gas volume ratio of GeH₄ to SiH₄ is greater than or equal to 1:10. In the embodiment, the materials of the semiconductor layer include microcrystalline silicon germanium, so the gases for forming the microcrystalline silicon germanium layer need to include H₂, SiH₄ and GeH₄, and the microcrystalline silicon germanium layer containing silicon Si and germanium Ge, i.e., the semiconductor layer, can be formed on the gate insulating layer after the ionization reaction of H₂ and GeH₄ and H₂ and SiH₄. Those skilled in the art can understand that a PECVD process can be used to deposit microcrystalline silicon germanium layers with H₂, SiH₄ and GeH₄ as reaction gases, and the process will not be described in detail here.

The gas volume ratio of H₂ to SiH₄ is selected to be greater than or equal to 20:1 and less than or equal to 180:1, H₂/GeH₄ is greater than or equal to 20:1 and less than or equal to 180:1, and GeH₄/SiH₄ is greater than or equal to 1:10. When H₂/SiH₄ and H₂/GeH₄ are lower than 20:1, the crystallinity of microcrystalline silicon germanium layer is poor. When the ratio of H₂/SiH₄ and H₂/GeH₄ is larger, the crystallinity of microcrystalline silicon germanium is better and the ratio of absorbing infrared light is higher and higher. On the other hand, germanium has a relatively small band gap and can easily absorb light of long wavelength, and the higher the proportion of germanium, the less visible light can be absorbed and the light leakage current can be effectively reduced. It should be noted that as the ratio of H₂/SiH₄ and H₂/GeH₄ increases and the ratio of GeH₄/SiH₄ increases, crystallite SiGe crystals increase and the crystallization effect becomes better and better, the absorption band of the corresponding crystallite SiGe layer does not overlap with the visible band and shifts to the infrared band, and the crystallite SiGe layer does not absorb visible light, then the crystallite SiGe layer will not generate light leakage current when used as a semiconductor layer.

The forbidden band gap of microcrystalline silicon germanium UC-SiGe is about 1 eV to 1.4 eV, and that of amorphous silicon is about 1.7-1.8 eV. The smaller the band gap, the easier it is for the material to absorb light of long wavelength, and the absorption band of amorphous silicon is in the visible light band, so the absorption band of microcrystalline silicon germanium with a band gap smaller than amorphous silicon moves toward the infrared light band longer than the visible light band. Those skilled in the art can make the absorption band of the microcrystalline silicon germanium layer completely non-overlapping with the visible light band by adjusting the parameter characteristics of the microcrystalline silicon germanium layer, for example, the absorption band of the microcrystalline silicon germanium layer can be adjusted to exceed 800 nm.

Alternatively, the materials of the semiconductor layer include microcrystalline germanium, and the reaction gases for forming the semiconductor layer include hydrogen H₂ and germanium hydride GeH₄, the gas volume ratio of H₂ to GeH₄ is greater than or equal to 20:1 and less than or equal to 180:1. In the embodiment, the material of the semiconductor layer includes microcrystalline germanium, so the gases for forming the microcrystalline germanium layer needs to include H₂ and GeH₄. After the ionization reaction of H₂ and GeH₄, the microcrystalline germanium layer containing Ge, i.e., the semiconductor layer, can be formed on the gate insulating layer. Those skilled in the art can understand that the PECVD process can be used to deposit microcrystalline germanium layers with H₂ and GeH₄ as the reaction gases, and the process will not be described in detail here. Here, H₂/GeH₄ is selected to be greater than or equal to 20:1 and less than or equal to 180:1. When H₂/GeH₄ is lower than 20:1, the crystallinity of microcrystalline germanium layer is poor. When the ratio of H₂/GeH₄ is larger, the crystallinity of microcrystalline germanium is better and the ratio of absorbing infrared light is higher and higher. On the other hand, germanium has a relatively small band gap, and germanium easily absorbs light of long wavelength, and cannot easily absorb visible light, such light leakage current is effectively reduced. It should be noted that as the H₂/GeH₄ ratio increases, crystallite germanium crystals increase and the crystallization effect becomes better and better, the absorption band of the corresponding crystallite germanium layer does not overlap with the visible band and shifts to the infrared band, and the crystallite germanium layer does not absorb visible light, thus no light leakage current will be generated when the crystallite germanium layer is used as a semiconductor layer.

The forbidden band gap of microcrystalline germanium UC-Ge is about 0.9 eV to 1.1 eV, and that of amorphous silicon is about 1.7 eV to 1.8 eV. However, the smaller the band gap, the easier it is for the material to absorb long wavelength light, and the absorption band of amorphous silicon is in the visible light band, so the absorption band of microcrystalline germanium with a band gap smaller than amorphous silicon moves toward the infrared light band longer than the visible light band. Those skilled in the art can make the absorption band of the microcrystalline germanium layer completely non-overlapping with the visible light band by adjusting the parameter characteristics of the microcrystalline germanium layer, for example, the absorption band of the microcrystalline germanium layer can be adjusted to exceed 800 nanometers.

It should be noted that, the present invention has been described with reference to the best modes and principle for carrying out the present invention, which is not intended to be limited by specific embodiment. It is apparent to those skilled in the art that a variety of modifications, changes and replacements may be made without departing from the scope of the present invention. Therefore, although the present invention is illustrated and described herein with reference to specific embodiments, the present invention is not intended to be limited to the details shown. Rather, various modifications may be made in the details within the scope and range of equivalents of the claims and without departing from the present invention.

What is claimed is:

1. A thin film transistor, comprising:
a substrate;
a gate electrode, a gate insulating layer, a semiconductor layer, a doping layer, and a source drain electrode all defined on the substrate in sequence, the semiconductor layer absorbing light having a wavelength greater than 760 nanometers.

2. The thin film transistor according to claim 1, wherein, the semiconductor layer absorbs light having the wavelength greater than 800 nanometers.

3. The thin film transistor according to claim 1, wherein, the thin film transistor is manufactured by four mask processes, the four mask processes sequentially comprise: forming a source drain metal layer by a one-time wet etching process, forming a doping film and a semiconductor film by a one-time dry etching process and ashing photoresist, forming the source drain electrode by a one-time wet etching process, and forming the doping layer and the semiconductor layer by a one-time dry etching process.

4. The thin film transistor according to claim 1, wherein a material of the semiconductor layer comprises microcrystalline silicon, microcrystalline silicon germanium, or microcrystalline germanium.

5. The thin film transistor according to claim 1, wherein a material of the doping layer comprises n-type amorphous silicon or p-type amorphous silicon.

6. The thin film transistor according to claim 1, wherein materials of the source drain electrode comprises molybdenum nitride, aluminum, and molybdenum nitride which are sequentially stacked.

7. A method for manufacturing a thin film transistor, wherein, the method comprises:
providing a substrate;
forming a gate electrode, a gate insulating layer, a semiconductor layer, a doping layer, and a source drain electrode on the substrate in sequence, wherein, the semiconductor layer absorbs light having a wavelength greater than 760 nanometers.

8. The method according to claim 7, wherein a material of the semiconductor layer comprises microcrystalline silicon, microcrystalline silicon germanium, or microcrystalline germanium.

9. The method according to claim 8, wherein the semiconductor layer is formed by a plasma enhanced chemical vapor deposition.

10. The method according to claim 9, wherein the temperature of the plasma enhanced chemical vapor deposition is in a range of 200 degrees Celsius to 500 degrees Celsius.

11. The method according to claim 9, wherein the plasma enhanced chemical vapor deposition lasts 120 seconds to 900 seconds.

12. The method according to claim 9, wherein the material of the semiconductor layer comprises microcrystalline silicon, and reaction gases for forming the semiconductor layer comprises: hydrogen H₂ and silicon tetrahydride SiH₄, wherein a gas volume ratio of H₂ to SiH₄ is greater than or equal to 20:1 and less than or equal to 180:1.

13. The method according to claim 9, wherein the material of the semiconductor layer comprises microcrystalline silicon germanium, and reaction gases for forming the semiconductor layer comprises: hydrogen H₂, silicon tetrahydride SiH₄, and germanium hydride GeH₄, wherein, a gas volume ratio of H₂ to SiH₄ is greater than or equal to 20:1 and less than or equal to 180:1, the gas volume ratio of H₂ to GeH₄ is greater than or equal to 20:1 and less than or equal to 180:1, and the gas volume ratio of GeH₄ to SiH₄ is greater than or equal to 1:10.

14. The method according to claim 9, wherein the material of the semiconductor layer comprises microcrystalline germanium, and reaction gases for forming the semiconductor layer comprises hydrogen H₂ and germanium hydride GeH₄, wherein a gas volume ratio of H₂ to Ge H₄ is greater than or equal to 20:1 and less than or equal to 180:1.

15. The method according to claim 7, wherein the thin film transistor is manufactured by four mask processes, the four mask processes comprises two wet etching processes and two dry etching process.

16. The method according to claim 15, wherein the four mask processes sequentially comprise: forming a source drain metal layer by a one-time wet etching process, forming a doping film and a semiconductor film by a one-time dry etching process and ashing photoresist, forming the source drain electrode by a one-time wet etching process, and forming the doping layer and the semiconductor layer by a one-time dry etching process.

17. A display panel, wherein, the display panel comprises a thin film transistor array substrate which comprises a thin film transistor;
the thin film transistor comprises:
a substrate;
a gate electrode, a gate insulating layer, a semiconductor layer, a doping layer, and a source drain electrode all defined on the substrate in sequence, the semiconductor layer absorbs light having a wavelength greater than 760 nanometers.

18. The display panel according to claim 17, wherein, the semiconductor layer absorbs light having the wavelength greater than 800 nanometers.

19. The display panel according to claim 17, wherein, the thin film transistor connects to a pixel electrode through an insulating layer.
